(19) United States
(12) Patent Application Publication
(10) Pub. No.: US 2015/0138876 A1
(43) Pub. Date: May 21, 2015

(54) GLOBAL BITLINE WRITE ASSIST FOR SRAM ARCHITECTURES

(71) Applicant: LSI Corporation, San Jose, CA (US)

(72) Inventors: Rajiv Kumar Roy, Bangalore (IN); Rasoju Veerabadra Chary, Bangalore (IN)

(73) Assignee: LSI CORPORATION, San Jose, CA (US)

(21) Appl. No.: 14/153,560

(22) Filed: Jan. 13, 2014

Related U.S. Application Data
(60) Provisional application No. 61/905,547, filed on Nov. 18, 2013.

(51) Int. Cl. G11C 11/419

(52) U.S. Cl. CPC G11C 11/419
USPC 365/154

(57) ABSTRACT

An SRAM device includes a segmented memory cell array with a plurality of memory cells. Each segment of memory cells includes a bitline coupled to the memory cells in the segment. The SRAM device further includes a global bitline traversing the segmented memory cell array and communicatively coupled to the memory cell segments via the local bitlines for writing to the memory cells. The SRAM device further includes a global input/output module operable to hold the global bitline at logical zero, to toggle the global bitline to logical one when data is to be written, to select one of the segments of memory cells for writing after the global bitline has been toggled, and to toggle the global bitline to logical zero when data is written to the selected memory cell segment to provide a negative boost voltage to the local bitline of the selected memory cell segment.

### CROSS REFERENCE TO RELATED APPLICATIONS

This patent application claims priority to, and thus the benefit of an earlier filing date from, U.S. Provisional Patent Application No. 61/905,547 (filed Nov. 18, 2013), the entire contents of which are hereby incorporated by reference.

### FIELD OF THE INVENTION

The invention generally relates to field of Synchronous Random Access Memories (SRAM) and more particularly to employing write assist.

### BACKGROUND

Submicron SRAM can experience write failures under certain operational conditions. To assist in this regard, “write assist” lines have been developed that pull bitlines below ground to ensure that logical zeros are written in memory cells. However, the circuitry associated with conventional write assist and so-called “negative boost” is costly both in terms of power consumption and area overhead.

### SUMMARY

SRAM devices herein improve power consumption and area overhead by employing write assist with global bitlines. In these configurations, the write assist line and associated write assist circuitry is eliminated and overall power consumption is reduced by applying a negative boost to local bitlines via the global bitlines. In one embodiment, the SRAM device includes a segmented memory cell array with a plurality of memory cells. Each segment of memory cells includes a bitline coupled to the memory cells in the segment. The SRAM device further includes a global bitline traversing the segmented memory cell array and communicatively coupled to the memory cell segments via the local bitlines for writing to the memory cells. The SRAM device further includes a global input/output module operable to hold the global bitline at logical zero, to toggle the global bitline to logical one when data is to be written, to select one of the segments of memory cells for writing after the global bitline has been toggled, and to toggle the global bitline to logical zero when data is written to the selected memory cell segment to provide a negative boost voltage to the local bitline of the selected memory cell segment.

The various embodiments disclosed herein may be implemented in a variety of ways as a matter of design choice. For example, some embodiments herein are implemented in hardware whereas other embodiments may include processes that are operable to construct and/or operate the hardware. Other exemplary embodiments are described below.

### BRIEF DESCRIPTION OF THE FIGURES

Some embodiments of the present invention are now described, by way of example only, and with reference to the accompanying drawings. The same reference number represents the same element or the same type of element on all drawings.

FIG. 1 is a block diagram of an exemplary memory array architecture 100 employing global bitline write assist.

FIG. 2 is a method for implementing write assist with a global bitline.

FIG. 3 illustrates an exemplary circuit diagram to implement write assist with a global bitline.

FIG. 4 illustrates an exemplary timing diagram for implementing write assist with a global bitline.

FIG. 5 illustrates another exemplary memory array architecture 100 employing global bitline write assist.

FIG. 6 illustrates another exemplary circuit diagram to implement write assist with a global bitline.

### DETAILED DESCRIPTION OF THE FIGURES

The figures and the following description illustrate specific exemplary embodiments of the invention. It will thus be appreciated that those skilled in the art will be able to devise various arrangements that, although not explicitly described or shown herein, embody the principles of the invention and are included within the scope of the invention. Furthermore, any examples described herein are intended to aid in understanding the principles of the invention and are to be construed as being without limitation to such specifically recited examples and conditions. As a result, the invention is not limited to the specific embodiments or examples described below.

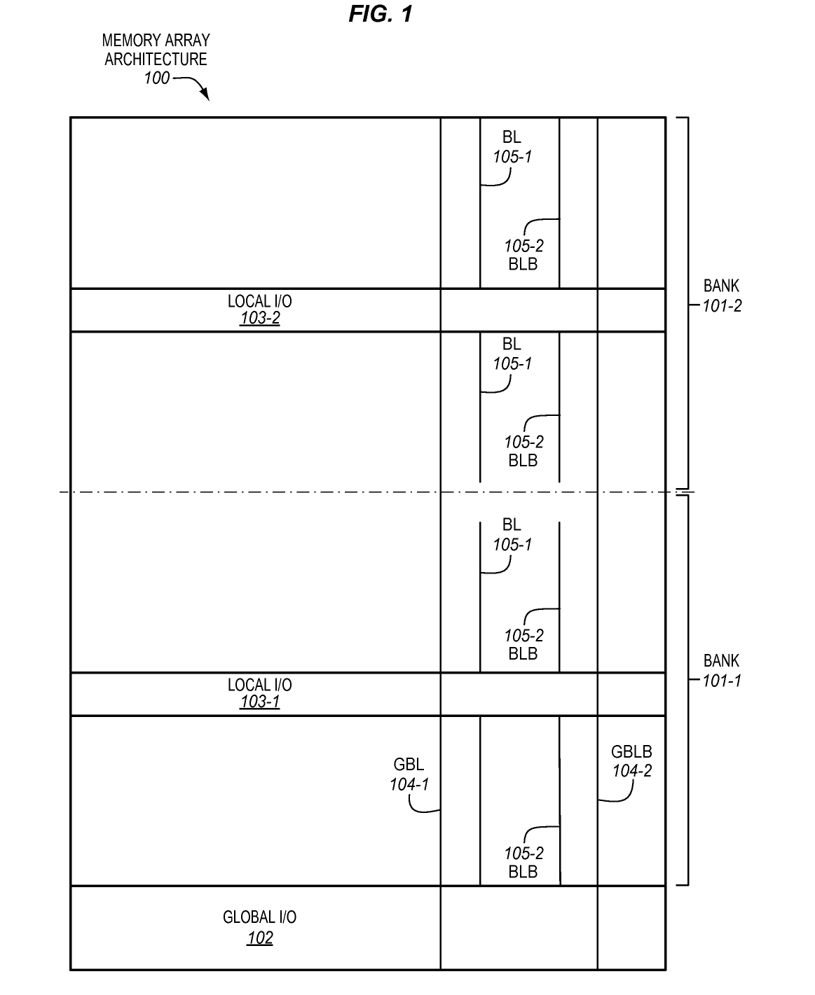

FIG. 1 is a block diagram of an exemplary memory array architecture 100 employing global bitline write assist. The memory array architecture 100 of FIG. 1 may be part of, for example, an SRAM device. Those skilled in the art will understand that additional components not shown or described in FIG. 1, such as drivers, latches, decoders, sense amps, etc. may be used to access memory cells in the memory array architecture 100. FIG. 1 is a simplified schematic view used to discuss the memory array architecture 100 but does not reflect the manner or in any way limit the physical implementation of the memory array architecture 100.

Memory cells (not shown) in the memory array architecture 100 are disposed at intersections of columns and rows. A global Input/Output (I/O) module 102 applies suitable control signals to selected word lines and bitlines to perform a read or write operation for memory cells located at a corresponding row and column. The memory cells may be segmented into multiple banks (e.g., bank 101-1 and 101-2), sometimes referred to as segments, as shown in FIG. 1. As such, each bank 101 may be configured with a local I/O module (e.g., 103-1, 103-2) communicatively coupled to the global I/O 102. The local I/O module 103 is operable to select one or more of the memory cells coupled to it for write and/or read operations when directed by the global I/O 102.

Memory cells in each bank 101 are configured in a lower metallization layer (i.e., a first metallization layer or substrate layer of a semiconductor device). Running in each of the banks 101 in column-wise fashion are bitlines 105. A local bitline 105 comprises a true local bitline (BL) 105-1 and a complement local bitline (BLB) 105-2, which are coupled to a corresponding local I/O module 103 and which are specific to a bank 101. The local bitlines 105 in this embodiment are configured in an upper metallization layer (i.e., a second metallization layer above the substrate layer of the semiconductor device).

Global bitlines 104 traverse the banks 101 in column-wise fashion in the upper metallization layer. A global bitline 104 comprises a true global bitline (GBL) 104-1 and a complement global bitline (GBLB) 104-2. Thus, each column of the memory array architecture 100 includes a global bitline 104 associated with multiple banks 101 (e.g., 101-1, 101-2, etc.) and a local bitline 105 specific to each bank 101. Both the global bitlines 104 and the local bitlines 104 run in the upper metallization layer. The global bitlines 104 are toggled by the global I/O module 102 and couple to the banks 101 via the local bitlines 105, thereby allowing write operations to be performed on memory cells.

The coupling that occurs between the global bitlines 104 and the local bitlines 105 in the upper metallization layer allows the global I/O module 102 to direct an appropriate negative boost to the local bitline 105 to assist in a write operation to a memory cell. Thus, global bitline 104 is used both for carrying data and for providing write assist via direct coupling with the local bitline 104. This eliminates the associated write assist circuitry that would normally be needed to provide a negative boost on the local bitline 105.

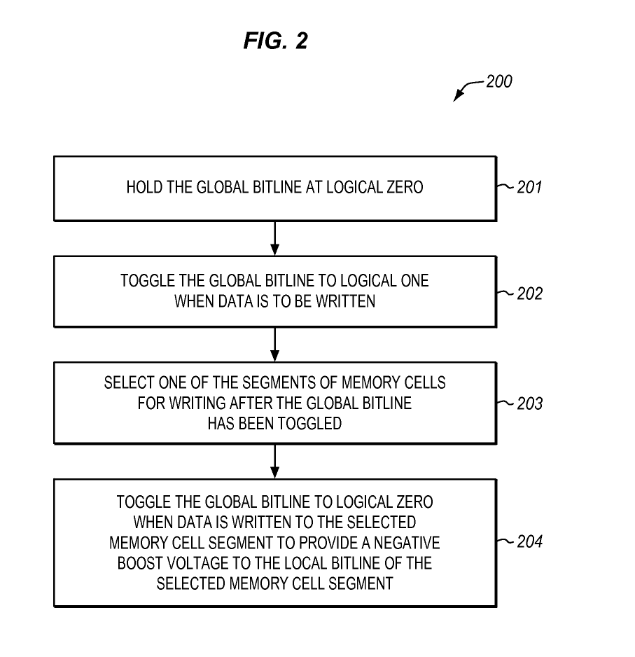

Discussion of the operation of the global I/O module 102 will now be directed to the flowchart of FIG. 2. Though directed to the memory array architecture 100 of FIG. 1, those skilled in the art will appreciate that the method 200 may be applicable to other embodiments, systems, and architectures. The steps of the flowchart described herein are not all inclusive and may include other steps not shown. Furthermore, while the steps are described with respect to a single memory cell, global I/O module 102 may perform the steps described herein on multiple memory cells in an independent and/or simultaneous fashion. For the sake of simplicity, the steps herein will be described with respect to a single column and bank of the memory array architecture 100, though additional columns and banks beyond that shown in FIG. 1 are possible.

FIG. 2 is a method for implementing write assist with a global bitline. In step 201 of the method 200, the global I/O module 102 holds the global bitline 104 at logical zero. When data is to be written to a memory cell, the global I/O module 102 toggles the global bitline 104 to logical one, at step 202. Then, at step 203, the global I/O module 102 selects a bank 101 for a write operation. At step 204, the global I/O module 102 toggles the global bitline 104 to logical zero when data is written to the selected bank 101. With the global bitline 104 and the local bitline 105 coupled in the upper metallization layer, this provides a negative boost of voltage to the local bitline 105 of the selected bank 101.

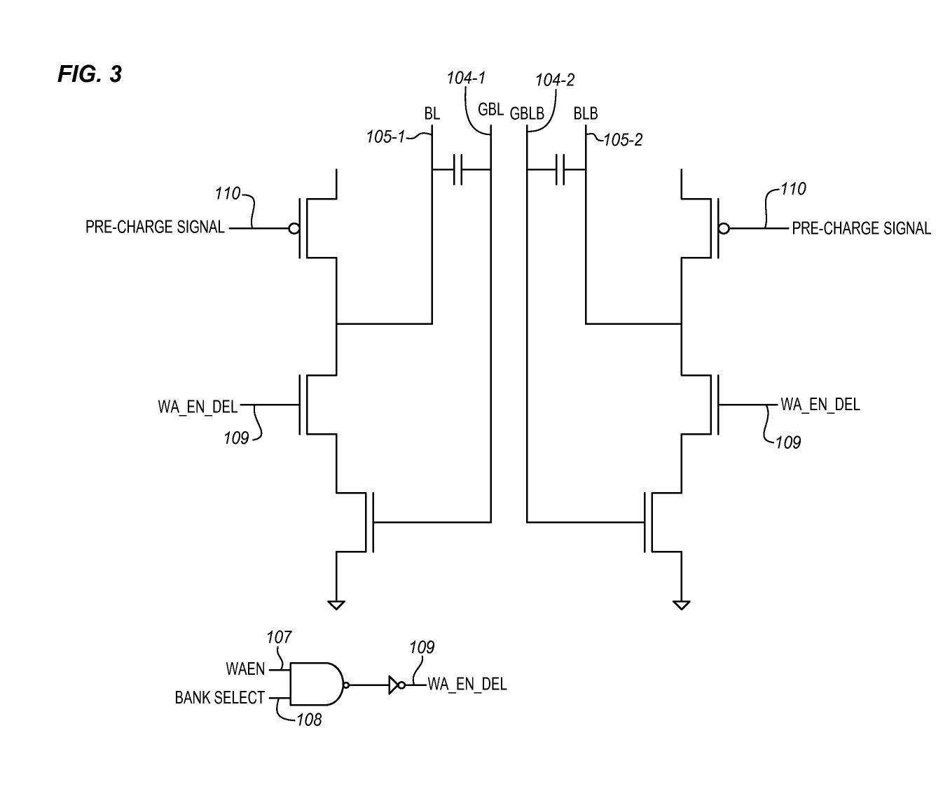

FIG. 3 illustrates an exemplary circuit diagram to implement write assist with a global bitline. Various signals provided by the global I/O module 102 and/or the local I/O module 103 enable write assist using the global bitline 104. As seen in FIG. 3, the global bitline 104 and the local bitline 105 are directly coupled via a capacitor formed due to bitlines running parallel to each other. In particular, the true portion of the global bitline 104 (i.e., 104-1) couples with the true portion of the local bitline 105 (i.e., 105-1). Similarly, the complement portion of the global bitline 104 (i.e., 104-2) couples with the complement portion of the local bitline 105 (i.e., 105-2). The signals used include, but are not limited to, a write enable signal 107, a bank select signal 108, a pre-charge signal 110, and combinations of the above (e.g., WA_EN_DEL signal 109).

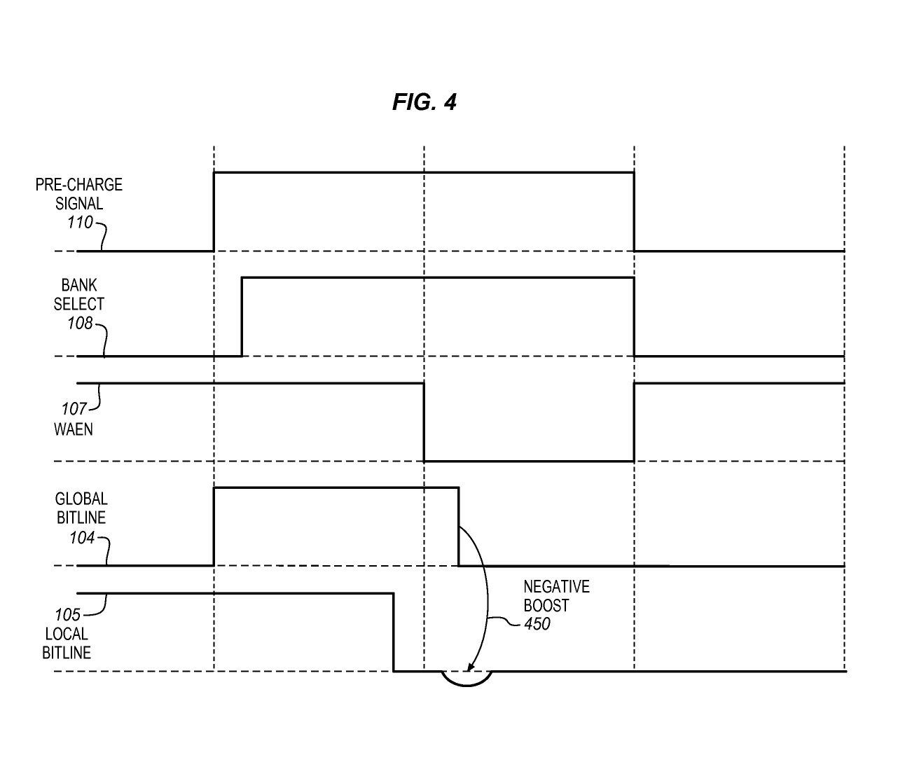

As mentioned, the circuitry of FIG. 3 eliminates a write assist line and its associated circuitry. Instead, the toggling associated with the global bitline 104 (i.e., GBL 104-1 or 104-2) provides negative boost on the corresponding local bitline 105 (i.e., BL 105-1 or 105-2). The order in which the various signals of FIG. 3 are toggled is more clearly explained in the exemplary embodiment of FIG. 4.

FIG. 4 illustrates an exemplary timing diagram for implementing write assist with a global bitline. The global bitline 104 is held at logical zero by default. Based on the data to be written, one bitline of the global bitline 104 (i.e., either GBL 104-1 or GBLB 104-2) is pulled high, which, for a selected bank, pulls a corresponding bitline of the local bitline 105 (i.e., either BL 105-1 or BLB 105-2) low. After that bitline of the local bitline 105 is pulled low, the write assist enable signal (WAEN 107) is pulled low, disabling the pull-down path of the local bitline 105. Then, the global bitline 105 is pulled low, and since it is coupled with the local bitline 105, it provides a negative voltage boost to the already low local bitline 105, as seen in element 450.

As an example, true global bitline 104-1 may be pulled high, which then transfers data onto its corresponding true local bitline 105-1 in a selected bank 101 by pulling the true local bitline 105-1 to logical zero. When the true local bitline 105-1 reaches logical zero, the true global bitline 104-1 is pulled low. Because of the coupling between the true global bitline 104-1 and the true local bitline 105-1, when the true global bitline 104-1 is pulled low it invokes a negative boost on the true local bitline 105-1 which assists in writing to a memory cell in the selected bank 101.

Thus, a negative boost on the local bitline 105 is provided without using a write assist line. And, the high to low transition of the global bitline 104 that provides the negative boost to the corresponding local bitline 105 does not consume any extra power since the global bitlines 104 are pulled low at the end of a write cycle anyway. Also, leakage in the global bitlines 104 is reduced since they are held at logical zero by default. The coupling between the global bitlines 104 and the local bitlines 105 also enables a relatively constant amount of negative boost throughout a range of rows of the memory cell architecture 100.

The bank 101 is selected by the global I/O module 102 by toggling the bank select signal 108 to logical one. Before a write operation of a particular memory cell, the precharge signal 110 may enable precharging of the local bitlines 105 to a known voltage such as voltage rail or supply voltage.

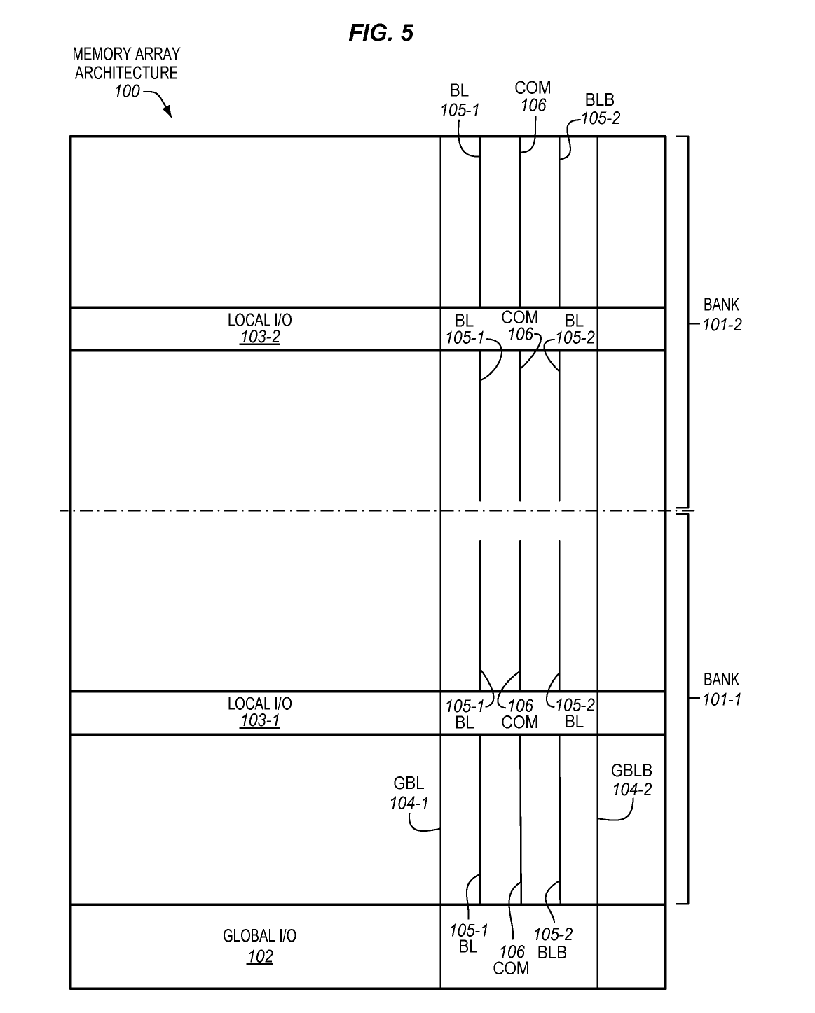

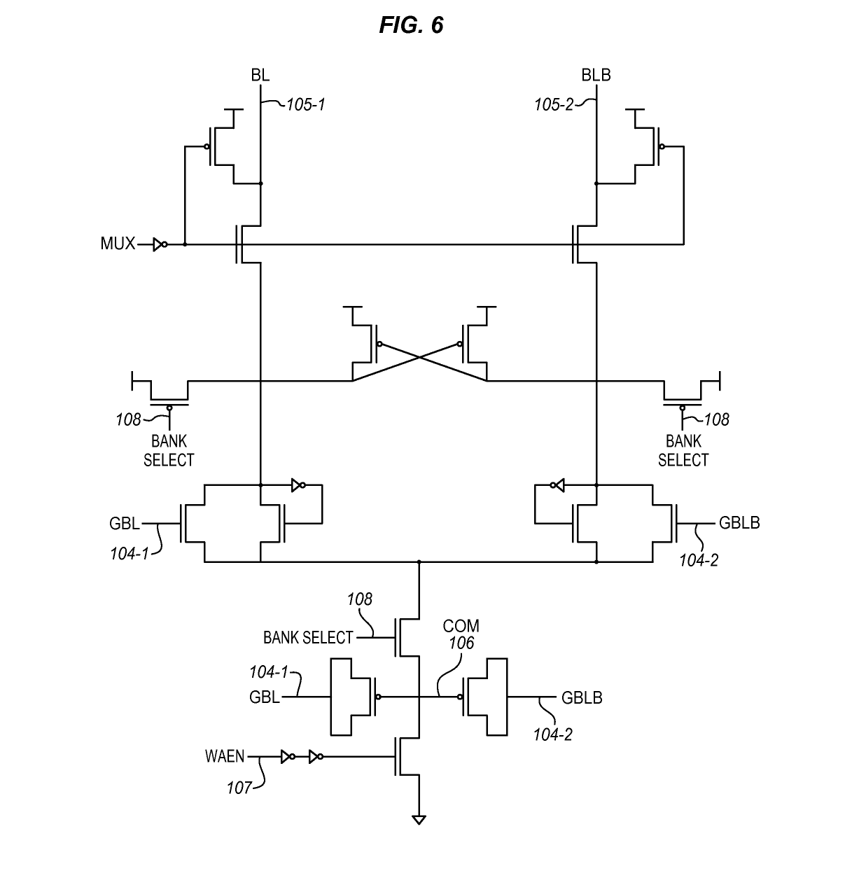

FIG. 5 illustrates another exemplary memory array architecture 100 employing global bitline write assist. In this embodiment, the global bitline 105 and the local bitline 104 may be configured in different metallization layers. The global bitline 105 couples directly with a common node of a write driver (e.g., COM 106) of the local I/O module 102. Thus, the local bitline 105 may be configured in the lower metallization layer along with the memory cells. The global bitline 104 and COM 106 are configured in upper metallization. The COM 106 in upper metallization may be substantially the same length as the local bitline 104 in lower metallization. Additional details of the circuitry to implement global bitline write assist in the memory array architecture 100 of FIG. 5 is described in FIG. 6.

FIG. 6 illustrates an exemplary circuit diagram to implement write assist with a global bitline in the memory array architecture 100 of FIG. 5. As with FIG. 5, the global bitline 104 and COM 106 (i.e., the common node of a write driver in a local I/O module 103) are configured in upper metallization and are directly coupled to one another. Due to the coupling between the global bitline 104 and COM 106, a negative boost is applied on COM 106 when one bitline of the global bitline 104 (e.g., 104-1 or 104-2) is pulled to logical zero after the COM 106 is already pulled low. The interaction between the global bitline 104 and the COM 106 is similar to the relationship between the global bitline 104 and the local bitline 105 already described above in FIGS. 2-4. With COM 106 routed over the local bitline 105 and with a similar run-length, the negative boost transfers from COM 106 to the local bitline 105 due to charge sharing. Thus, the circuitry of FIG. 6 enables the global bitline 104 to transfer data onto a corresponding local bitline 105, and to provide write assistance by applying a negative voltage to a common node of a write driver without any additional write assist circuitry.

It will be appreciated that the terms upper, lower, first, second, and the like in the description are used for distinguishing between similar elements and not necessarily for describing a particular orientation or order. In other words, the terms so used are interchangeable under appropriate circumstances and the embodiments of the disclosure herein can operate in orientations and sequences other than that which is described or illustrated herein. Additionally, those skilled in the art will understand that the embodiments discloses herein may be applicable to a number of different multi-bank and split bitline architectures.

What is claimed is:

1. A Static Random Access Memory device, comprising:
a segmented memory cell array comprising a plurality of memory cells, wherein each segment of memory cells comprises a local bitline coupled to the memory cells in the segment;
a global bitline traversing the segmented memory cell array and communicatively coupled to the memory cell segments via the local bitlines for writing to the memory cells; and
a global input/output module operable to hold the global bitline at logical zero, to toggle the global bitline to logical one when data is to be written, to select one of the segments of memory cells for writing after the global bitline has been toggled, and to toggle the global bitline to logical zero when data is written to the selected memory cell segment to provide a negative boost voltage to the local bitline of the selected memory cell segment.

2. The Static Random Access Memory device of claim 1, wherein:
each memory cell segment is configured with a local input/output module communicatively coupled to the global input/output module and operable to select the memory cell segment for writing when directed by the global input/output module.

3. The Static Random Access Memory device of claim 2, wherein:
the global input/output module is further operable to provide a write assist signal on the global bitline to assist the local bitline of the selected memory cell segment in writing to a memory cell of the selected memory cell segment.

4. The Static Random Access Memory device of claim 3, wherein:
wherein the global bitline and the local bitline are directly coupled and configured in an upper metallization layer; and
wherein the memory cells are configured in a lower metallization layer.

5. The Static Random Access Memory device of claim 3, wherein:
each memory cell segment further comprises a common node configured in the upper metallization layer and the local bitline in the lower metallization layer; and
the global bitline in the upper metallization layer provides the negative boost voltage to the common node of the selected memory cell segment.

6. The Static Random Access Memory device of claim 1, wherein:
the global bitline is directly coupled to the local bitline of each memory cell segment through a capacitor.

7. A method operable in a Static Random Access Memory device, the method comprising:
with a global bitline traversing a segmented memory cell array and coupled to a local bitline in each of the memory cell segments, holding the global bitline at logical zero;
toggling the global bitline to logical one when data is to be written;
selecting one of the segments of memory cells for writing after the global bitline has been toggled; and
toggling the global bitline to logical zero to logical zero when data is written to the selected memory cell segment to provide a negative boost voltage to the local bitline of the selected memory cell segment.

8. The method of claim 7, wherein selecting one of the segments of memory cells for writing further comprises:
transferring a select signal from a global input/output module to a local input/output module configured with the selected memory cell segment.

9. The method of claim 8, further comprising:
providing a write assist signal from the global input/output module to the local input/output module of the selected memory cell segment to assist the local bitline of the selected memory cell segment in writing to a memory cell of the selected memory cell segment.

10. The method of claim 7, wherein:
wherein the global bitline and the local bitline are configured in an upper metallization layer and the memory cells are configured in a lower metallization layer.

11. The method of claim 7, wherein:
each memory cell segment further comprises a common node configured in the upper metallization layer and the local bitline in the lower metallization layer; and
the global bitline in the upper metallization layer provides the negative boost voltage to the common node of the selected memory cell segment.

12. The method of claim 7, wherein:
the global bitline is directly coupled to the local bitline of each memory cell segment through a capacitor.
